(19) United States
(12) Patent Application Publication
(10) Pub. No.: US 2025/0241062 A1
(43) Pub. Date: Jul. 24, 2025

(54) STRUCTURE WITH TWO WORK FUNCTION METALS OVER CONDUCTIVE BRIDGE, AND METHOD TO FORM SAME

(71) Applicant: GlobalFoundries U.S. Inc., Malta, NY (US)

(72) Inventors: David C. Pritchard, Schenectady, NY (US); Galla K. Kumar, Bangalore (IN); Romain H.A. Feuillette, Williston, VT (US); Navneet K. Jain, Milpitas, CA (US); Steven J. Bentley, Menands, NY (US); George R. Mulfinger, Queensbury, NY (US); Hong Yu, Clifton Park, NY (US)

(21) Appl. No.: 18/415,955

(22) Filed: Jan. 18, 2024

(51) Int. Cl. H01L 27/12; H01L 21/8234; H01L 27/085

(52) U.S. Cl. CPC H10D 86/201; H10D 84/0144; H10D 84/0149; H10D 84/038; H10D 84/82

(57) ABSTRACT

A structure, including an insulator within a substrate. The substrate includes a first active region adjacent a first sidewall of the insulator and a second active region adjacent a second sidewall of the insulator opposite the first sidewall. The structure further includes a conductive bridge over the insulator and coupling the first active region of the substrate to the second active region of the substrate. The structure includes a gate dielectric layer over the conductive bridge, a first work function metal over the first active region, and a second work function metal over the second active region.

### BACKGROUND

Embodiments of the disclosure relate generally to integrated circuit (IC) structures. More particularly, the disclosure relates to IC structures with two work function metals over a conductive bridge.

Integrated circuit (IC) chips have billions of devices thereon, such as transistors, capacitors, and resistors. Certain device applications require devices with increased power demands. However, as higher voltages are applied across IC devices, such as transistors, those devices break down due to, for example, hot carrier injection across device dielectric layers. Therefore, relieving stress drain stress and improving hot carrier injection reliability allows for increased device performance and lifespan.

### SUMMARY

An aspect of the disclosure includes a structure, comprising: an insulator within a substrate, wherein the substrate includes a first active region adjacent a first sidewall of the insulator and a second active region adjacent a second sidewall of the insulator opposite the first sidewall; a conductive bridge over the insulator and coupling the first active region of the substrate to the second active region of the substrate; a gate dielectric layer over the conductive bridge; a first work function metal over the first active region; and a second work function metal over the second active region.

Another aspect of the disclosure includes a structure, comprising: a semiconductor-on-insulator stack (SOI stack) including a semiconductor layer, a buried insulator over the semiconductor layer, and an active semiconductor layer over the buried insulator; a first insulator within the SOI stack and having an upper surface above the active semiconductor layer, wherein the first insulator is horizontally between a first active region and a second active region of the active semiconductor layer; a first conductive bridge over the insulator and coupling the first active region of the active semiconductor layer to the second active region of the active semiconductor layer; a gate dielectric layer over the first conductive bridge; a first work function metal over the first active region; and a second work function metal over the second active region.

Another aspect of the disclosure includes a method, comprising: forming an insulator within a substrate, wherein the substrate includes a first active region adjacent a first sidewall of the insulator and a second active region adjacent a second sidewall of the insulator opposite the first sidewall, wherein an upper surface of the insulator is above the substrate; forming a conductive bridge over the insulator and coupling the first active region of the substrate to the second active region of the substrate; forming a gate dielectric layer over the conductive bridge; forming a first work function metal over the first active region; and forming a second work function metal over the second active region.

It should be noted that all aspects, examples, and features of disclosed embodiments mentioned herein can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1A shows a perspective view of a structure with two work function metals over a conductive bridge according to embodiments of the disclosure.

FIG. 1B shows a cross-sectional view of a structure according to embodiments of the disclosure.

FIG. 1C shows a cross-sectional view of a structure according to further embodiments of the disclosure.

FIG. 1D shows a cross-sectional view of a structure according to further embodiments of the disclosure.

FIG. 1E shows a cross-sectional view of a structure according to further embodiments of the disclosure.

FIG. 2A shows a perspective view of a structure with two conductive bridges according to further embodiments of the disclosure.

FIG. 2B shows a perspective view of a structure with two conductive bridges according to further embodiments of the disclosure.

FIG. 2C shows an enlarged partial cross-sectional view of box 2C in FIG. 2B.

FIG. 2D shows an enlarged partial cross-sectional view of box 2D in FIG. 2B.

FIG. 3 shows a preliminary structure for processing according to embodiments of the disclosure.

FIG. 4 shows a structure after forming a mask over a conductive layer, according to embodiments of the disclosure.

FIG. 5 shows a structure after forming a conductive bridge, according to embodiments of the disclosure.

FIG. 6 shows a structure after forming a gate dielectric with multiple layers, according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B,” and “at least one of A and B,” is intended to encompass the selection of the first listed option (A) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Embodiments of the disclosure include an insulator within a substrate. The substrate includes a first active region adjacent a first sidewall of the insulator and a second active region adjacent a second sidewall of the insulator opposite the first sidewall. The structure further includes a conductive bridge over the insulator and coupling the first active region of the substrate to the second active region of the substrate. The structure includes a gate dielectric layer over the conductive bridge, a first work function metal over the first active region, and a second work function metal over the second active region. By including a conductive bridge in the structure, the structure has improved performance by exhibiting less parasitic capacitance or hot carrier injection than in conventional structures.

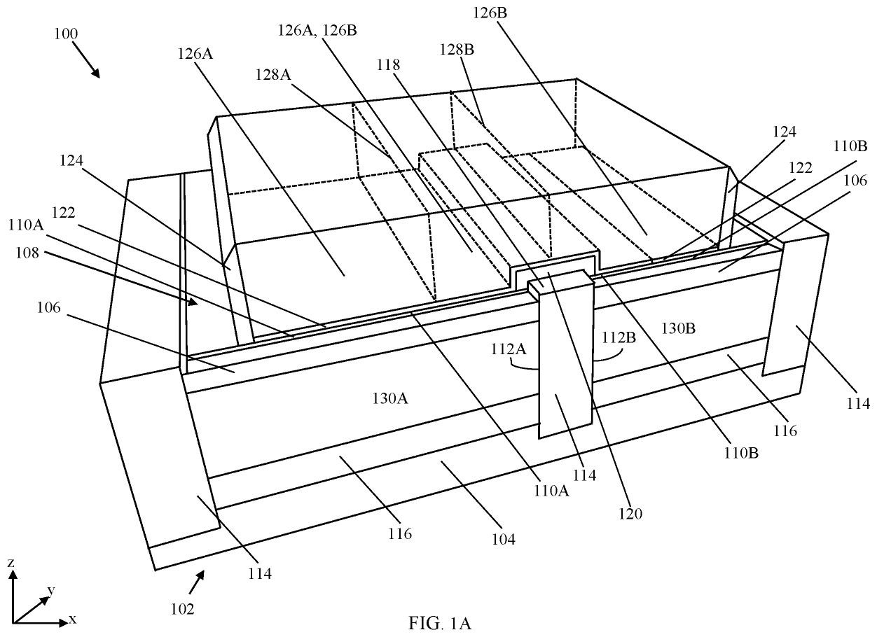

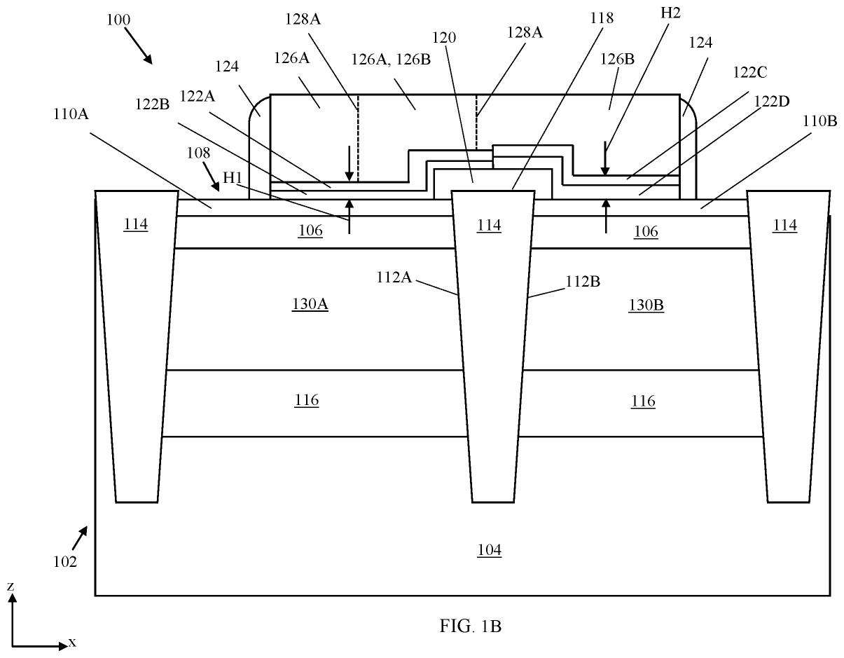

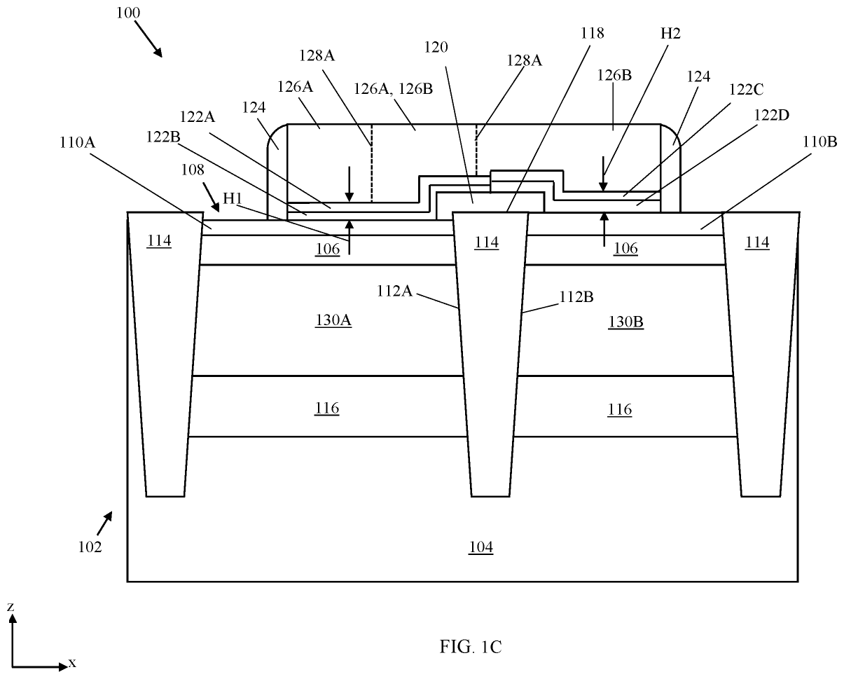

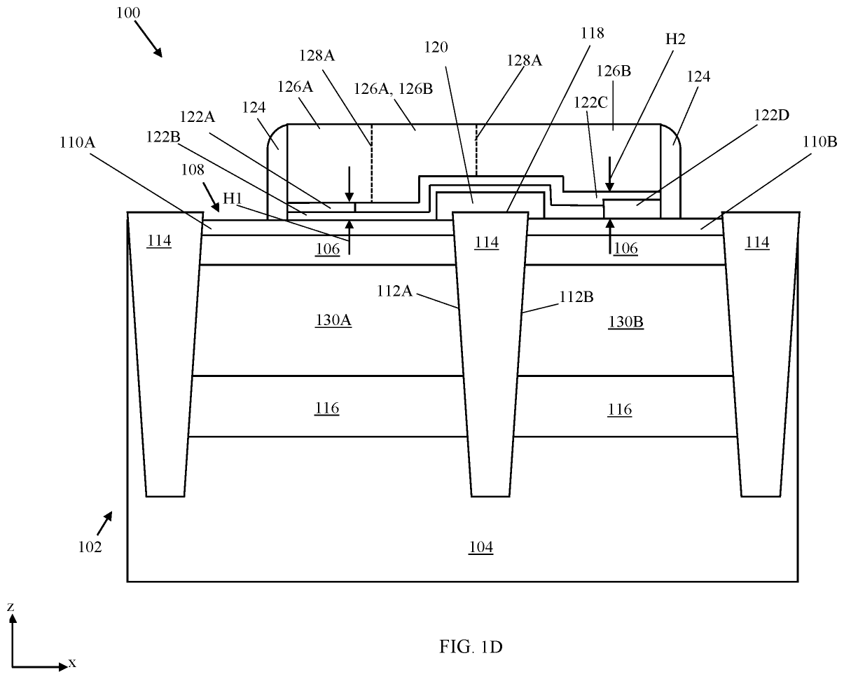

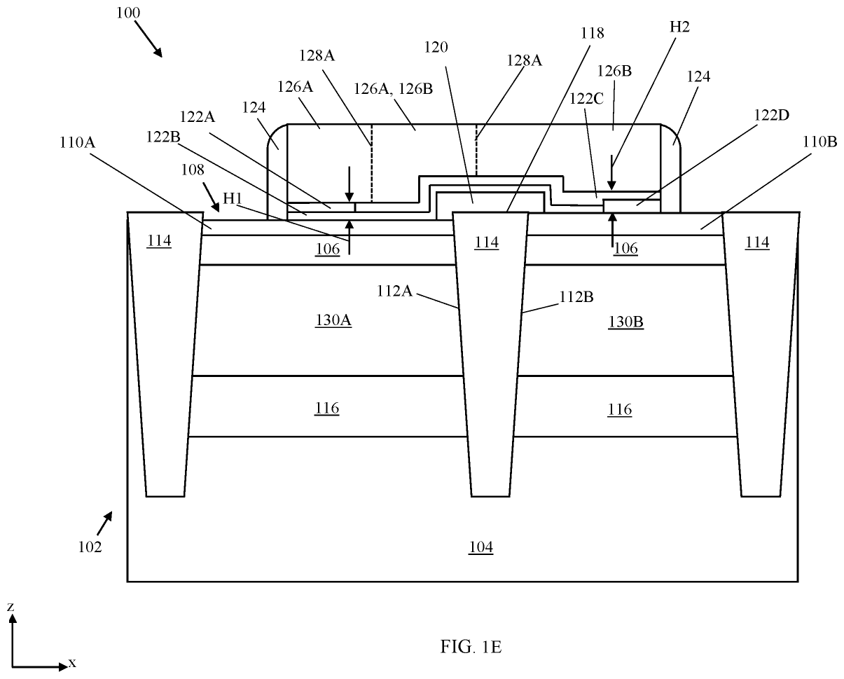

FIGS. 1A-E show various views of a structure 100, according to embodiments of the disclosure. In particular, FIG. 1A shows a perspective x-y-z view of structure 100, and FIGS. 1B-E show cross-sectional side views of structure 100 in the z-y plane. Structure 100 may take the form of, or include, any feasible semiconductor device, such transistors, capacitors, resistors, inductors, etc.

Still referring to FIGS. 1A-E, structure 100 may include a substrate 102. Substrate 102 may provide, e.g., mechanical support to portions of structure 100 thereover. Substrate 102 may include any known or future material capable of being a substrate, including any known or future-discovered semiconductors. Substrate 102 may include but is not limited to silicon, germanium, silicon germanium (SiGe), silicon carbide, or any other common integrated circuit (IC) semiconductor substrates. In the case of SiGe, the germanium concentration in substrate 102 may differ from other SiGe-based structures described herein. A portion or entirety of substrate 102 may be strained. Substrate 102 may take the form of a semiconductor-on-insulator (SOI) substrate (hereinafter “SOI stack”) in some implementations, including a semiconductor layer 104, a buried insulator 106 over semiconductor layer 104, and an active semiconductor layer 108 over buried insulator 106. Semiconductor layer 104 and active semiconductor layer 108 each may include semiconducting materials and may be used for electrical conduction, while buried insulator 106 may include a dielectric (i.e., non-conductive) material. In some implementations, substrate 102 may further include a first active region 110A adjacent a first sidewall 112A of an insulator 114 and a second active region 110B adjacent a second sidewall 112B of insulator opposite first sidewall 112A. First active region 110A and second active region 110B are electrically active regions of (i.e., connected to a voltage source) of substrate 102. Similar to buried insulator 106, insulator 114 is a dielectric (non-conductive) material. As shown in FIGS. 1B-E, the vertical thickness of active semiconductor layer 108 may be uniform (FIGS. 1B and 1D) or non-uniform (FIGS. 1C and 1E), i.e., first active region 110A and second active region 110B may each have different vertical thicknesses from one another.

Substrate 102 may include wells 116 therein. Doped portions of a substrate may be known in the art as a “well.” A well commonly refers to the implanted/diffused region in semiconductor wafer needed to implement a complementary metal oxide semiconductor (CMOS) cell. A “deep well” refers to doped semiconductor material located underneath active device components and/or other wells. A “shallow well,” similar to a deep well, is an area of doped semiconductor material located beneath active device components but not to the same depth as a deep well. Hence, it is possible for a highly doped active semiconductor material to be located inside of a shallow well or deep well, and/or for the shallow well in turn to be located inside of a deep well. Additional levels of wells may be provided in further device structures, e.g., to produce a “triple well” stack of doped semiconductor materials and/or more complex arrangements of layers having distinct doping polarities and/or types. Depending on the attributes of a device to be manufactured, portions of semiconductor material on or over substrate 102 may be either n-type or p-type doped as discussed herein.

As previously mentioned, structure 100 may include insulator 114 within substrate 102. Insulator 114 may extend vertically from semiconductor layer 104 to some position above substrate 102, i.e., an upper surface 118 of insulator 114 may be above substrate 102. Insulator 114 may be a non-electrically-conducting material and may include, for example, one or more layers of silicon dioxide, silicon nitride, a doped silicon glass (e.g., phosphosilicate glass (PSG) or borophosphosilicate glass (BPSG)), or any other suitable dielectric material. As mentioned previously, substrate 102 may include first active region 110A adjacent first sidewall 112A of insulator 114 and second active region 110B adjacent second sidewall 112B of insulator 114 opposite first sidewall 112A. An active region is an electrically active region of (i.e., connected to a voltage source) substrate 102. Although only two additional insulators 114 are illustrated on either side of structure 100 in plane X-Z, structure 100 may include any number of additional insulators.

First active region 110A and second active region 110B may be substantially similar to other semiconducting regions disclosed herein, e.g., it may include silicon and dopants. “Doping” and “dopants” herein refer to altering a semiconductor material's conducting properties by introducing an impurity therein. Different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region. Furthermore, when a semiconductor region or layer is described as being at a higher conductivity level than another semiconductor region or layer, it is more conductive (less resistive) than the other semiconductor region or layer; whereas, when a semiconductor region or layer is described as being at a lower conductivity level than another semiconductor region or layer, it is less conductive (more resistive) than that other semiconductor region or layer.

Structure 100 may include a conductive bridge 120 over insulator 114 coupling first active region 110A of substrate 102 to second active region 110B of substrate 102. Conductive bridge 120 may have one or more electrically conductive materials for electrically bridging first active region 110A and second active region 110B. Conductive bridge 120 is distinct from, for example, a transistor channel region, because conductive bridge 120 is invariably conductive and does not include, e.g., a depletion region therein that would allow for the variable resistivity of a channel region. Conductive bridge 120 may be thicker (i.e., have a greater vertical height) than first active region 110A and second active region 110B, thereby improving hot carrier injection (“HCI”) by dampening strain in first active region 110A and/or second active region 110B. Conductive bridge 120 may include a doped semiconductor material. The doped semiconductor material may be similar to other doped semiconductor materials described herein. In other implementations, conductive bridge 120 may include any other semiconductor material, such as epitaxially-grown semiconductors, amorphous semiconductors, undoped (i.e., intrinsic) semiconductors, etc.

Structure 100 may include a gate dielectric layer 122 over conductive bridge 120. Gate dielectric layer 122 prevents charge carriers (e.g., electrons) from migrating from portions thereover into conductive bridge 120 below. Gate dielectric layer 122 may be similar to other electrically insulative or non-conductive materials disclosed herein (e.g., insulator 114). Also shown in FIGS. 1B-C, gate dielectric layer 122 may include a first layer 122A over a second layer 122B, and a third layer 122C over a fourth layer 122D. All layers may be the same or different materials, or any combination thereof. Although only four gate dielectric layers are illustrated, gate dielectric layer 122 may include any number of layers. A vertical thickness of gate dielectric layer 122 may be non-uniform, as shown in FIGS. 1B-E, i.e., gate dielectric layer 122 may include different vertical thicknesses over any of first active semiconductor layer 110A, second active semiconductor layer 110B, or conductive bridge 120. In some embodiments, shown in FIGS. 1B-E, vertical thickness of gate dielectric layer 122 is uniform above first active region 110A, and non-uniform above second active region 110B. In particular, a first vertical thickness H1 of gate dielectric layer 122 above first active semiconductor layer 110A may be less than a second vertical thickness H2 of gate dielectric layer 122 above second active region.

Structure 100 may include a first work function metal 126A over first active region 110A and a second work function metal 126B over second active region 110B. The work function of a metal refers to the minimum amount of energy required to remove an electron from the metal's surface to a point just outside the metal. The work function of, e.g., a gate metal influences the threshold voltage (i.e., the required voltage to switch the transistor current at a predetermined level and is, generally, the required voltage to invert the charge carriers in a channel region) by increasing or decreasing the energy barrier for electrons to move from the source to the drain. Conductive bridge 120 under first work function metal 126A and/or a second work function metal 126B electrically connects, e.g., two devices without a break in the active area therebetween. This enables devices with different work functions to be connected directly. First work function metal 126A and second work function metal 126B may include various metals depending on whether for an NFET or PFET device, but may include, for example: aluminum (Al), zinc (Zn), indium (In), copper (Cu), indium copper (InCu), tin (Sn), tantalum (Ta), tantalum nitride (TaN), tantalum carbide (TaC), titanium (Ti), titanium nitride (TiN), titanium carbide (TiC), TiAlC, TiAl, tungsten (W), tungsten nitride (WN), tungsten carbide (WC), polycrystalline silicon (poly-Si), and/or combinations thereof. As shown in FIGS. 1B-C, first work function metal 126A abuts second work function metal 126B over one of first active region 110A and conductive bridge 120. Two interfaces 128A and 128B (illustrated as dashed lines) are shown in FIGS. 1A-C to illustrate that, in some implementations, first work function metal 126A may abut second work function metal 126B over one of first active region 110A and conductive bridge 120. The material(s) between first interface 128A and second interface 128B are alternatively labeled as first work function metal 126A and second work function metal 126B because, depending on whether structure 100 includes first interface 128A or second interface 128B, the middle portion may take the form of first work function metal 126A or second work function metal 126B. In some implementations, first work function metal 126A has a greater work function than second work function metal 126B. In yet other implementations, however, second work function metal 126B may have a greater work function than first work function metal 126A.

Structure 100 may include other gate materials, e.g., gate spacers 124, gate cap, etc. Gate spacers 124 may be on opposing sides of first work function metal 126A and second work function metal 126B and/or may include one or more layers of isolation material (e.g., silicon nitride, silicon dioxide, silicon oxynitride, or any other suitable gate sidewall spacer isolation material).

Structure 100 may include first back biasing region 130A within semiconductor layer 104 below first work function metal 126A, and a second back biasing region 130B within semiconductor layer 104 below second work function metal 126B. Back biasing refers to how some transistors, such as fully-depleted semiconductor-on-insulator transistors, are “turned on,” i.e., biased. Thus, a back biasing region is a region within structure 100 to which a voltage is applied to allow structure 100 to conduct charge carriers therein.

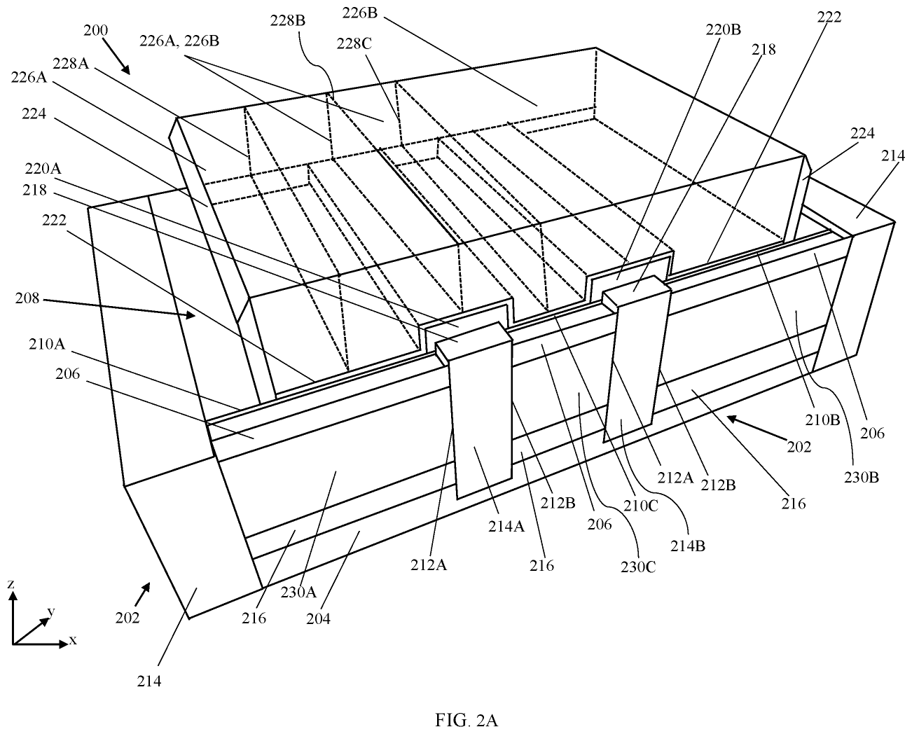

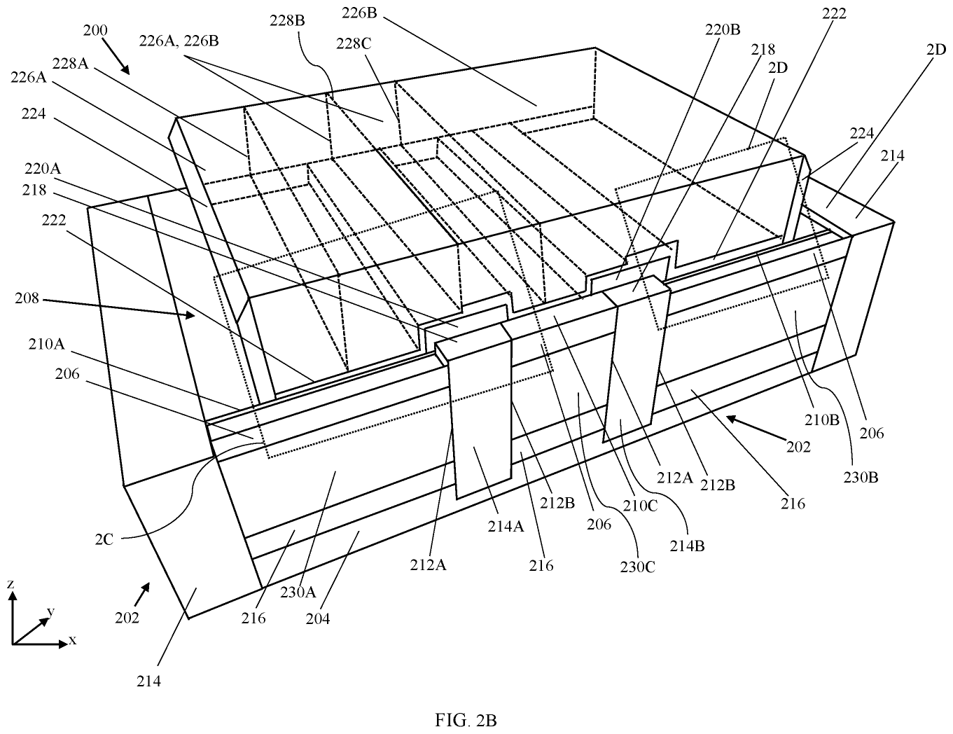

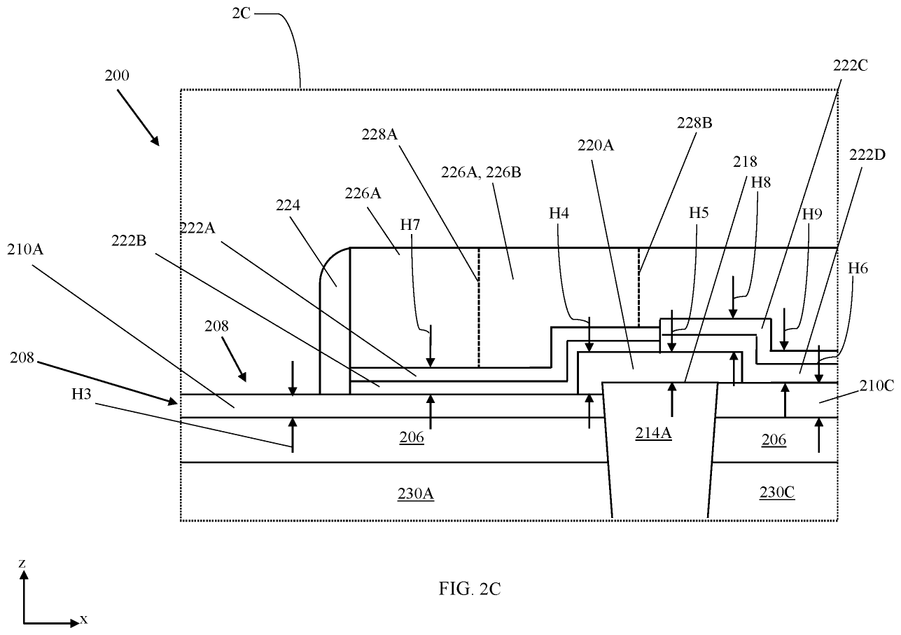

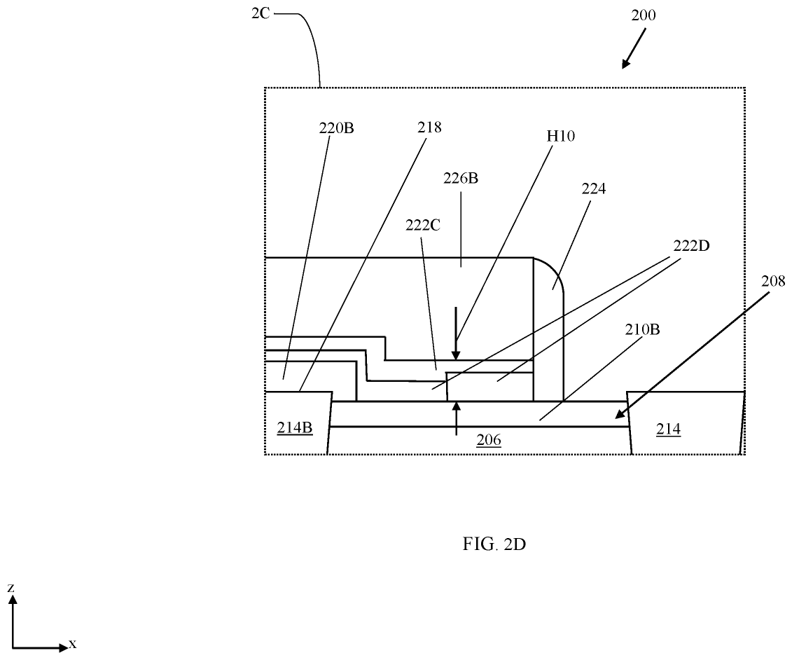

In other embodiments shown in FIGS. 2A-D, structure 200 may include a semiconductor-on-insulator stack (SOI stack) 202 similar to SOI stacks described in other implementations, i.e., SOI stack 202 may include semiconductor layer 204, buried insulator layer 206 over semiconductor layer 204, and active semiconductor layer 208 over buried insulator layer 206. That is, SOI stack 202 may include a layered semiconductor-insulator-semiconductor substrate instead of a conventional semiconductor substrate (i.e., semiconductor layer 204). SOI stack 202 may include active semiconductor layer 208 (which may take the form of, e.g., an SOI layer) over buried insulator layer 206 over semiconductor layer 204. Active semiconductor layer 208 and semiconductor layer 204 may include any semiconductor described in other implementations herein. Buried insulator layer 206 may be similar to other insulators described herein, e.g., buried insulator layer 206 may include any appropriate dielectric such as but not limited to silicon dioxide, i.e., forming a buried oxide (BOX) layer. A portion of or the entire semiconductor layer 204 may be strained. The precise thickness of buried insulator layer 206 and active semiconductor layer 208 may vary widely with the intended application. For example, SOI stack 202 may take the form of a fully depleted semiconductor-on-insulator, or fully depleted (FD)-SOI, stack, which is a planar process technology that uses a buried insulator layer 206 (also referred to in the art as a “buried oxide (BOX)”) positioned on top of the semiconductor layer 204, and an active semiconductor layer 208 over buried insulator layer 206. SOI stack 202 may further include a first active region 210A adjacent a first sidewall 212A of an insulator 214 and a second active region 210B adjacent a second sidewall 212B of insulator 214 opposite first sidewall 212A. First active region 210A and second active region 210B are electrically active regions of (i.e., connected to a voltage source) of SOI stack 202. Similar to buried insulator layer 206, insulator 214 is a dielectric (non-conductive) material. First insulator 214A may also include upper surface 218 above active semiconductor layer 208.

SOI stack 202 may optionally include wells 216 therein. Wells 216 may be similar or even the same as wells 116 in other implementations. That is, doped portions of an SOI stack may be known in the art as a “well.” A well commonly refers to the implanted/diffused region in semiconductor wafer needed to implement a complementary metal oxide semiconductor (CMOS) cell. Here, wells 216 may be any polarity (i.e., n-type or p-type).

Structure 200 may include insulators 214 within SOI stack 202. In some implementations, structure 200 may include a second insulator 214B adjacent first insulator 214 (hereinafter “first insulator 214A” and “second insulator 214B”). First insulator 214A and second insulator 214B may be substantially similar or even identical to insulator 114 in other implementations. First insulator 214A may include an upper surface 218 above active semiconductor layer 208. First insulator 214A and second insulator 214B may be horizontally between first active region 210A and second active region 210B of active semiconductor layer 208, as shown in FIGS. 2A and 2B.

As previously mentioned, structure 200 may include first active region 210A and second active region 210B on either side of first insulator 214A. First active region 210A and second active region 210B may be substantially similar to first active region 110A and second active region 110B in other implementations. Structure 200 may further include an intermediate active region 210C of active semiconductor layer 208 adjacent second insulator 214B. Active semiconductor region 208 may be optionally uniform or non-uniform in vertical thickness over any portion of structure 200. That is, in some implementations, active semiconductor layer 208 is substantially uniform, as shown in FIG. 2A. In other implementations, shown in FIG. 2B and best illustrated in FIG. 2C, which shows an enlarged partial cross-section of structure 200, active semiconductor layer 208 may be non-uniform, i.e., the vertical thickness of active semiconductor layer 208 may be non-uniform, i.e., first active region 210A, second active region 210B, and intermediate active region 210C may each have different vertical thicknesses from one another or relative to other components. In particular, first active region 210A may include a first vertical thickness H3 less than a second vertical thickness H4 or third vertical thickness H5 of a conductive bridge 220, as shown in FIGS. 2B-C. Conductive bridge 220 is a structure that is electrically conductive and electrically bridges first active region 210A and other active regions (e.g., intermediate active region 210C) and is substantially similar to conductive bridge 120 in other implementations. In other implementations, a fourth vertical thickness H6 of intermediate active region 210C may be greater than first vertical thickness H3 of first active region 210A but less than second and third vertical thicknesses H4 and H5 of conductive bridge 220.

Structure 200 may include first conductive bridge 220A over first insulator 214A and electrically coupling first active region 210A of active semiconductor layer 208 to second active region 210B of active semiconductor layer 208 and may further include a second conductive bridge 220B over second insulator 214B. First conductive bridge 220A and second conductive bridge 220B may be substantially similar or even identical to conductive bridge 120 described in other implementations. As shown in FIGS. 2A-B, first conductive bridge 220A may be under first work function metal 226A and second conductive bridge 220B may be beneath second work function metal 226B. In other implementations, and as described previously and as shown in FIGS. 2B-C, active semiconductor layer 208 may have a different vertical thickness than first conductive bridge 220A. Specifically, as best shown in FIG. 2C, active semiconductor layer 208 may include a first vertical thickness H1 less than a second vertical thickness H2 of the first conductive bridge 220A. Additionally, conductive bridges 220A and 220B may have non-uniform vertical thicknesses, i.e., second vertical thickness H4 may be greater over first active region 210A than a third vertical thickness H5 over first insulator 214A, as shown in FIG. 2C.

Structure 200 may include gate dielectric layer 222 over first conductive bridge 220A. Gate dielectric layer 222 may be substantially similar to gate dielectric layer(s) 122A-D described in other implementations (e.g., in FIGS. 1A-C), i.e., gate dielectric layer 222 may include a first dielectric layer 222A (FIG. 2C), second dielectric layer 222B (FIG. 2C), third dielectric layer 222C (FIG. 2D), and fourth dielectric layer 222D (FIG. 2D). The individual gate dielectric layers 222A-D are unillustrated in FIGS. 2A-B for simplicity, and are best illustrated in FIGS. 2C-D. In some implementations, a vertical thickness of the gate dielectric layer 222 may be uniform (FIG. 2A) or non-uniform (i.e., location-dependent, as shown in FIGS. 2B-D). In one embodiment, best illustrated in FIG. 2C, gate dielectric layer 222 may have a fifth vertical thickness H7 over first active region 210A less than a sixth vertical thickness H8 over first conductive bridge 220A. In another embodiment, also shown in FIG. 2C, gate dielectric layer 222 may include a seventh vertical thickness H9 greater than fifth vertical thickness H7. In yet another embodiment, best illustrated in FIG. 2D, which is an enlarged partial cross-section of box 2D in FIG. 2B, gate dielectric layer may include an eight vertical thickness H10 greater than fifth vertical thickness H7 (FIG. 2C). Structure 200 may include other gate materials, e.g., gate spacers 224, gate cap, etc. Gate spacers 224 may be on either side of first work function metal 226A and second work function metal 226B and may include one or more layers of isolation material (e.g., silicon nitride, silicon dioxide, silicon oxynitride, or any other suitable gate sidewall spacer isolation material).

Structure 200 may include first work function metal 226A over first active region 210A and second work function metal 226B over second active region 210B. First work function metal 226A and second work function metal 226B may be substantially similar or even identical to first work function metal 126A and second work function metal 126B in other implementations described herein. That is, the work function of, e.g., a gate metal influences the threshold voltage (i.e., the required voltage to switch the transistor current at a predetermined level and is, generally, the required voltage to invert the charge carriers in a channel region) by increasing or decreasing the energy barrier for electrons to move from the source to the drain. First conductive bridge 220A and/or second conductive bridge 220B under first work function metal 226A and/or a second work function metal 226B electrically connect, e.g., two devices without a break in the active area therebetween. This enables devices with different work functions to be connected directly. In some implementations, first work function metal 226A abuts second work function metal 226B over one of first active region 210A and intermediate active region 210C (interfaces are illustrated as dashed lines). Three interfaces 228A, 228B, and 228C are illustrated in FIG. 2 to illustrate that, in some implementations, first work function metal 226A may abut second work function metal 226B over one of first active region 210A, first conductive bridge 220A, or first intermediate active region 210C.

Structure 200 may include first back biasing region 230A within semiconductor layer 204 below first work function metal 226A, and a second back biasing region 230B within semiconductor layer 204 below second work function metal 226B. Back biasing refers to how some transistors, such as fully-depleted semiconductor-on-insulator transistors, are “turned on,” i.e., biased. Thus, a back biasing region is a region within structure 200 is a region to which a voltage is applied to allow structure 200 to conduct charge carriers therein. Structure 200 may further include an intermediate back biasing region 230C within semiconductor layer 204 and horizontally between first back biasing region 230A and second back biasing region 230B.

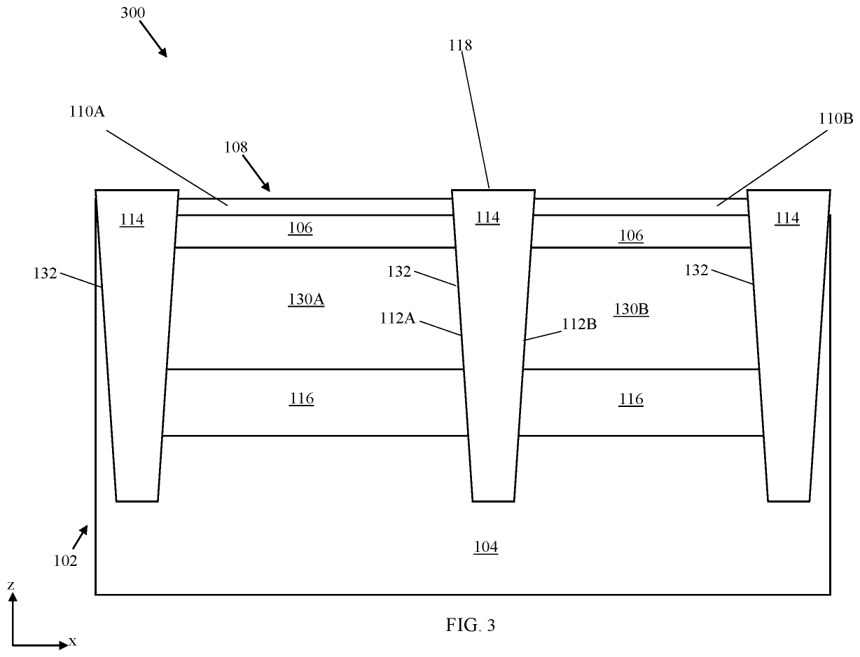

Embodiments of the disclosure provide methods to form structure 100 according to various embodiments. FIGS. 3-6 show cross-sectional views of a structure at various stages of fabrication.

Referring to FIG. 3, structure 300 may include substrate 102 on which other components are formed. Substrate 102 may be similar to substrate 102 in other implementations, and may include first active region 110A and second active region 110B pre-formed thereon, as in the case where substrate 102 takes the form of an SOI stack or FDSOI stack. In other implementations, however, forming method may include forming first active region 110A adjacent first sidewall 112A of insulator 114 and forming second active region 110B adjacent second sidewall 112B of insulator 114 opposite first sidewall 112A. First active region 110A and second active region 110B may be formed by, for example, doping substrate 102. “Doping” is the process of introducing impurities (dopants) into, e.g., a semiconductor substrate 102, or elements formed on the semiconductor substrate 102, and is often performed with a mask (or previously-formed, elements in place) so that only certain areas of the substrate 102 will be doped. For example, doping is used to form the source and drain regions of a field effect transistor. An ion implanter is typically employed for the actual implantation. An inert carrier gas such as nitrogen is usually used to bring in the impurity source (i.e., dopants).

The methods described herein may include forming first back biasing region 130A within semiconductor layer 104 (and ultimately below first active region 110A, as shown in FIG. and forming a second back biasing region 130B within semiconductor layer 104 below second active region 110B by, e.g., doping semiconductor layer 104.

Still referring to FIG. 3, the methods described herein may include forming insulator 114 within substrate 102. Upper surface 118 of insulator 114 may be above substrate 102. Insulator 114 may be formed by, for example, patterning a portion of active semiconductor layer 108 and semiconductor layer 104 and depositing an insulating material in a trench 132 (portion insulator is in FIG. 3). “Deposition” and “depositing” may include any now known or later developed techniques appropriate for the material to be deposited including but are not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

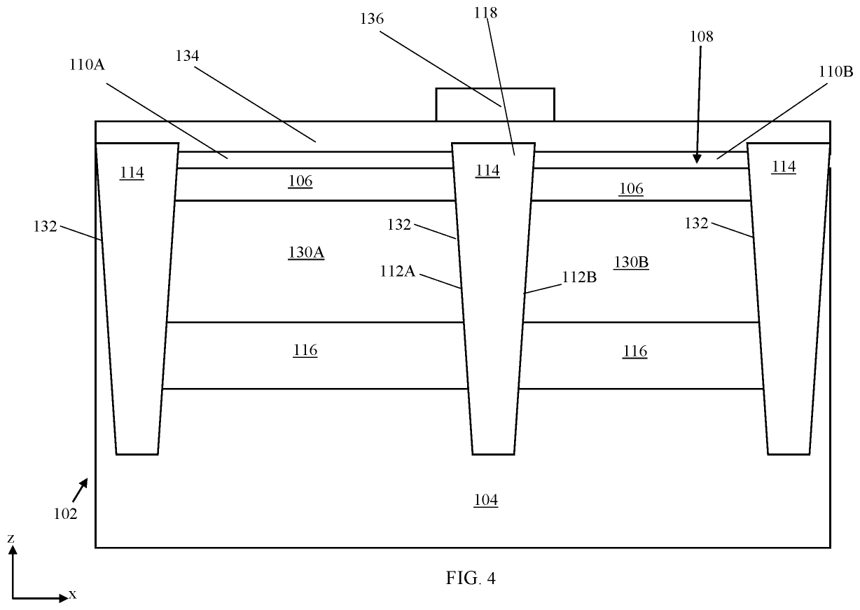

Referring to FIG. 4, the methods described herein may include forming conductive bridge 120 over insulator 114 and coupling first active region 110A of substrate 102 to second active region 110B of substrate 102. Conductive bridge 120 may include a doped semiconductor material. Conductive bridge 120 may be formed by, for example, depositing or epitaxially growing a semiconductor layer 134 over insulator 114. The terms “epitaxial growth” and “epitaxially formed and/or grown” mean the growth of a semiconductor material on a deposition surface of a semiconductor material, in which the semiconductor material being grown may have the same crystalline characteristics as the semiconductor material of the deposition surface. In an epitaxial growth process, the chemical reactants provided by the source gases are controlled and the system parameters are set so that the depositing atoms arrive at the deposition surface of the semiconductor substrate 102 with sufficient energy to move around on the surface and orient themselves to the crystal arrangement of the atoms of the deposition surface. Therefore, an epitaxial semiconductor material may have the same crystalline characteristics as the deposition surface on which it may be formed. For example, an epitaxial semiconductor material deposited on a <100> crystal surface may take on a <100> orientation. In some embodiments, epitaxial growth processes may be selective to forming on semiconductor surfaces, and may not deposit material on dielectric surfaces, such as silicon dioxide or silicon nitride surfaces.

Still referring to FIG. 4, forming conductive bridge 120 may include forming a mask 136 over semiconductor layer 134. The term “mask” may be given to a layer of material which is applied over an underlying layer of material, and patterned to have openings, so that the underlying layer can be processed where there are openings. After processing the underlying layer, mask 136 may be removed. Common masking materials are photoresist (resist) and nitride. Nitride is usually considered to be a “hard mask.” Mask 136 may include a developable organic planarization layer (OPL) on the layer to be etched, a developable anti-reflective coating (ARC) layer on the developable OPL, and a photoresist mask layer on the developable ARC layer. Masks may be removed using any known removal process appropriate for the mask material, e.g., a wet etch for hard nitride mask or an ashing process (oxygen dry strip process) for a soft resist-based mask.

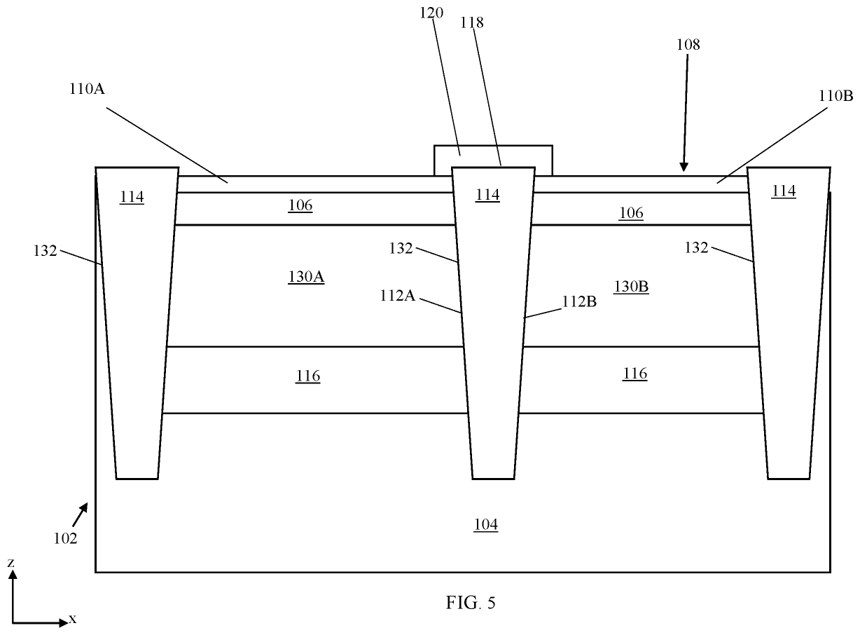

Referring to FIG. 5, forming conductive bridge 120 may further include patterning semiconductor layer 134 and removing mask 136 by, e.g., etching. “Etching” generally refers to the removal of material from a substrate (or structures formed on the substrate) and is often performed with a mask in place so that material may selectively be removed from certain areas of the substrate, while leaving the material unaffected, in other areas of the substrate. There are generally two categories of etching, (i) wet etch and (ii) dry etch. Wet etch is performed with a solvent (such as an acid) which may be chosen for its ability to selectively dissolve a given material (such as oxide), while, leaving another material (such as polysilicon) relatively intact. This ability to selectively etch given materials is fundamental to many semiconductor fabrication processes. A wet etch will generally etch a homogeneous material (e.g., oxide) isotropically, but a wet etch may also etch single-crystal materials (e.g. silicon wafers) anisotropically. Dry etch may be performed using a plasma. Plasma systems can operate in several modes by adjusting the parameters of the plasma. Ordinary plasma etching produces energetic free radicals, neutrally charged, that react at the surface of the wafer. Since neutral particles attack the wafer from all angles, this process is isotropic. Ion milling, or sputter etching, bombards the wafer with energetic ions of noble gases which approach the wafer approximately from one direction, and therefore this process is highly anisotropic. Reactive-ion etching (RIE) operates under conditions intermediate between sputter and plasma etching and may be used to produce deep, narrow features, such as STI trenches.

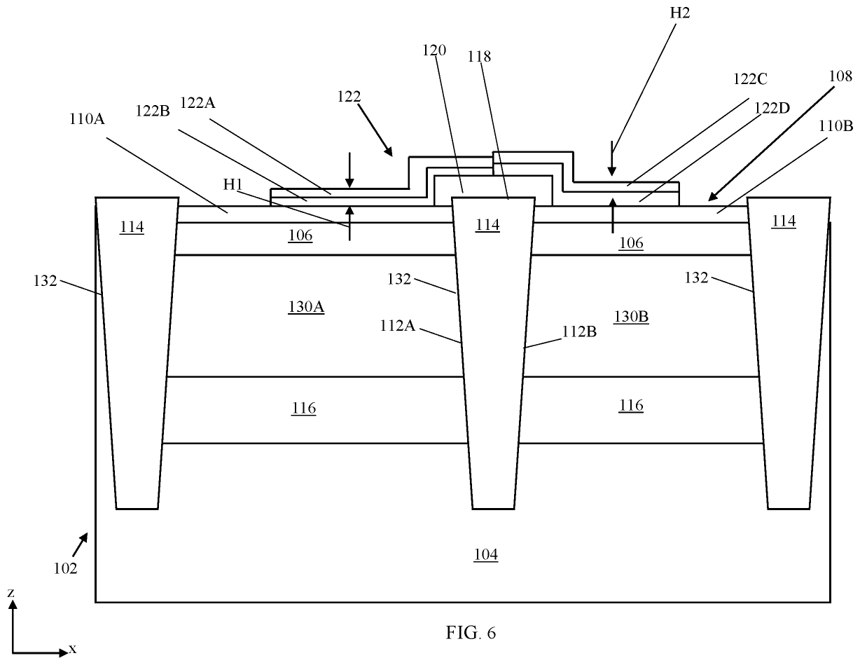

Referring to FIG. 6, the methods described herein may include forming gate dielectric layer 122 over conductive bridge 120. Gate dielectric layer 122 may include a first layer 122A and a second layer 122B over first layer 122A, and a third layer 122C over a fourth layer 122D. Forming gate dielectric layer 122 may include depositing dielectric material and selectively etching portions thereof. The vertical thickness of gate dielectric layer 122 may be formed as non-uniform. In other implementations, vertical thickness of gate dielectric layer 122 may be uniform above first active region 110A, and non-uniform above second active region 110B or conductive bridge 120, as shown in FIG. 6, i.e., gate dielectric layer may include different vertical thicknesses over any of first active semiconductor layer 110A, second active semiconductor layer 110B, or conductive bridge 120. In some implementations, also shown in FIG. 6, a first vertical thickness H1 of gate dielectric layer 122 above first active semiconductor layer 110A may be less than a second vertical thickness H2 of gate dielectric layer 122 above second active region 110B. Gate dielectric layer 122 may be formed by, e.g., deposition and may include any dielectric material.

The methods described herein may include forming first work function metal 126A over first active region 110A, and forming second work function metal 126B over second active region 110B to form final structure 100 illustrated in FIG. 1B. First work function metal 126A may be formed abutting second work function metal 126B over one of first active region 110A and conductive bridge 120. First work function metal 126A and second work function metal 126B may be formed by, e.g., deposition and subsequently planarized by, e.g., chemical mechanical polishing. Planarization refers to various processes that make a surface more planar (that is, flatter and/or smoother than its original state). Chemical-mechanical-polishing (“CMP”) is one currently conventional planarization process which planarizes surfaces with a combination of chemical reactions and mechanical forces. CMP uses slurry including abrasive and corrosive chemical components along with a polishing pad and retaining ring, typically of a greater diameter than the wafer. The pad and wafer are pressed together by a dynamic polishing head and held in place by a plastic retaining ring. The dynamic polishing head is rotated with different axes of rotation (that is, not concentric). This process removes material and tends to even out any “topography,” making the wafer flat and planar. Other currently conventional planarization techniques may include: (i) oxidation; (ii) chemical etching; (iii) taper control by ion implant damage; (iv) deposition of films of low-melting point glass; (v) resputtering of deposited films to smooth them out; (vi) photosensitive polyimide (PSPI) films; (vii) new resins; (viii) low-viscosity liquid epoxies; (ix) spin-on glass (SOG) materials; and/or (x) sacrificial etch-back.

The methods described herein may include forming other gate materials, e.g., gate spacers 124, gate cap, etc. Gate spacers 124 may be formed on either side of first work function metal 126A and second work function metal 126B by, e.g., deposition.

Embodiments of the disclosure include a conductive bridge over an insulator. By including a conductive bridge in structure 100, structure 100 has improved performance without creating or increasing parasitic capacitance or hot carrier injection or increasing the layout area of structure 100. Further, a non-uniform gate dielectric layer increases the gate voltage that structure 100 can tolerate.

The method and structure as described above are used in the fabrication and operation of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure, comprising:
an insulator within a substrate, wherein the substrate includes a first active region adjacent a first sidewall of the insulator and a second active region adjacent a second sidewall of the insulator opposite the first sidewall;
a conductive bridge over the insulator and coupling the first active region to the second active region of the substrate;
a gate dielectric layer over the conductive bridge;
a first work function metal over the first active region; and
a second work function metal over the second active region.

2. The structure of claim 1, wherein an upper surface of the insulator is above the substrate.

3. The structure of claim 1, wherein a vertical thickness of the gate dielectric layer is non-uniform.

4. The structure of claim 1, wherein a first vertical thickness of the gate dielectric layer above the first active region is less than a second vertical thickness of the gate dielectric layer above the second active region.

5. The structure of claim 1, wherein the first work function metal abuts the second work function metal over one of the first active region and the conductive bridge.

6. The structure of claim 1, wherein the first work function metal has a greater work function than a work function of the second work function metal.

7. A structure, comprising:
a semiconductor-on-insulator stack (SOI stack) including a semiconductor layer, a buried insulator over the semiconductor layer, and an active semiconductor layer over the buried insulator;
a first insulator within the SOI stack, wherein the SOI stack includes a first active region adjacent a first sidewall of the first insulator and a second active region adjacent a second sidewall of the first insulator opposite the first sidewall, wherein an upper surface of the first insulator is above the active semiconductor layer;
a first conductive bridge over the first insulator and coupling the first active region of the active semiconductor layer to the second active region of the active semiconductor layer;
a gate dielectric layer over the first conductive bridge;
a first work function metal over the first active region; and
a second work function metal over the second active region.

8. The structure of claim 7, wherein a vertical thickness of the active semiconductor layer is non-uniform.

9. The structure of claim 7, wherein the first conductive bridge includes a doped semiconductor material.

10. The structure of claim 7, further comprising:
a second insulator adjacent the first insulator;
a second conductive bridge over the second insulator; and
an intermediate active region of the active semiconductor layer adjacent the second insulator.

11. The structure of claim 10, wherein a vertical thickness of the gate dielectric layer is non-uniform.

12. The structure of claim 10, wherein the first conductive bridge is under the first work function metal and the second conductive bridge is beneath the second work function metal.

13. The structure of claim 10, further comprising:
a first back biasing region within the semiconductor layer below the first work function metal;
a second back biasing region within the semiconductor layer below the second work function metal; and
an intermediate back biasing region within the semiconductor layer and horizontally between first back biasing region and the second back biasing region.

14. The structure of claim 10, wherein the first work function metal abuts the second work function metal over one of the first active region and the intermediate active region.

15. The structure of claim 7, wherein a vertical thickness of the active semiconductor layer is less than a vertical thickness of the first conductive bridge.

16. A method, comprising:
forming an insulator within a substrate, wherein the substrate includes a first active region adjacent a first sidewall of the insulator and a second active region adjacent a second sidewall of the insulator opposite the first sidewall;
forming a conductive bridge over the insulator and coupling the first active region to the second active region of the substrate;
forming a gate dielectric layer over the conductive bridge;
forming a first work function metal over the first active region; and
forming a second work function metal over the second active region.

17. The method of claim 16, wherein an upper surface of the insulator is above the substrate.

18. The method of claim 16, wherein a vertical thickness of the gate dielectric layer is non-uniform.

19. The method of claim 16, wherein a first vertical thickness of the gate dielectric layer above the first active region is less than a second vertical thickness of the gate dielectric layer above the second active region.

20. The method of claim 16, wherein the first work function metal abuts the second work function metal over one of the first active region and the conductive bridge.
